(19) United States
(12) Patent Application Publication
(10) Pub. No.: US 2017/0040089 A1
(43) Pub. Date: Feb. 9, 2017

(54) METHODS OF PREPARING CONDUCTORS, CONDUCTORS PREPARED THEREFROM, AND ELECTRONIC DEVICES INCLUDING THE SAME

(71) Applicant: SAMSUNG ELECTRONICS CO., LTD., Suwon-si (KR)

(72) Inventors: Jongmin LEE, Hwaseong-si (KR); Se Yun KIM, Seoul (KR); Jong Wook ROH, Anyang-si (KR); Doh Won JUNG, Seoul (KR); Sungwoo HWANG, Suwon-si (KR); Chan KWAK, Yongin-si (KR)

(21) Appl. No.: 15/215,825

(22) Filed: Jul. 21, 2016

(30) Foreign Application Priority Data
Aug. 3, 2015 (KR) 10-2015-0109555

(51) Int. Cl. H01B 13/00; G06F 3/041; H01B 5/02

(52) U.S. Cl. CPC H01B 13/0036; H01B 5/02; G06F 3/041

(57) ABSTRACT

A method of preparing a conductor including a first conductive layer including a plurality of metal oxide nanosheets, the method including: preparing a coating liquid including a plurality of metal oxide nanosheets, wherein an intercalant is attached to a surface of the nanosheets, applying the coating liquid to a substrate to provide a first conductive layer including a plurality of metal oxide nanosheets, and performing a surface treatment on the first conductive layer to remove at least a portion of the intercalant.

### CROSS-REFERENCE TO RELATED APPLICATION

This application claims priority to Korean Patent Application No. 10-2015-0109555 filed in the Korean Intellectual Property Office on Aug. 3, 2015, and all the benefits accruing therefrom under 35 U.S.C. §119, the content of which is incorporated herein in its entirety by reference.

### BACKGROUND

1. Field

Methods of preparing conductors, conductors prepared therefrom, and electronic devices including the same are disclosed.

2. Description of the Related Art

An electronic device like a flat panel display, such as an LCD or LED, a touch screen panel, a solar cell, a transparent transistor, and the like may include an electrically conductive film or a transparent electrically conductive film. It is desirable for a material of an electrically conductive film to have high light transmittance (e.g., greater than or equal to about 80% in a visible light region) and low specific resistance (e.g., less than or equal to about 1×10⁻⁴ Ω·cm). Currently available oxide materials for electrically conductive films include indium tin oxide (ITO), tin oxide (SnO₂), zinc oxide (ZnO), and the like. The ITO as a transparent electrode material is a transparent semiconductor having a wide bandgap of 3.75 eV, and may be manufactured into a large area using a sputtering process. However, to be used in a flexible touch panel, or a UD-grade high resolution display, conventional ITO has poor flexibility and inevitably high cost due to limited reserves of indium. Therefore, development of an alternative material is critical.

Recently, a flexible electronic device has been drawing attention as a next generation electronic device. Therefore, there is a need for development of a transparent material having relatively high electrical conductivity and flexibility, as well as the transparent electrode materials. Herein, the flexible electronic device may include a bendable or foldable electronic device.

### SUMMARY

An embodiment provides a method of preparing a flexible conductor having improved conductivity, improved light transmittance, and decreased haze.

Another embodiment provides a conductor prepared therefrom.

Yet another embodiment provides an electronic device including the conductor.

In an embodiment, a method of preparing a conductor including a first conductive layer including a plurality of metal oxide nanosheets, the method including:

preparing a coating liquid including a plurality of metal oxide nanosheets, wherein an intercalant is attached to a surface of the nanosheets;

applying the coating liquid to a substrate to provide a first conductive layer including a plurality of metal oxide nanosheets; and

performing a surface treatment on the first conductive layer to remove at least a portion of the intercalant.

The metal oxide nanosheet may include TiₓO₂ (wherein x=0.8 to 1.0), Ti₃O₇, Ti₄O₉, Ti₅O₁₁, Ti₁₋ₓCoₓO₂ (wherein 0<x≦0.2), Ti₁₋ₓFeₓO₂ (wherein 0<x≦0.4), Ti₁₋ₓMnₓO₂ (wherein 0<x≦0.4), Ti_{0.8-x/4}Fe_{x/2}CO_{0.2-x/4}O₂ (wherein x=0.2, 0.4, or 0.6), MnO₂, Mn₃O₇, Mn₁₋ₓCoₓO₂ (wherein 0<x≦0.4), Mn₁₋ₓFeₓO₂ (wherein 0<x≦0.2), TiNbO₅, Ti₂NbO₇, TiTaO₅, Nb₃O₈, Nb₆O₁₇, TaO₃, LaNb₂O₇, La_{0.90}Eu_{0.05}Nb₂O₇, Eu_{0.56}Ta₂O₇, SrTa₂O₇, Bi₂SrTa₂O₉, Ca₂Nb₃O₁₀, Sr₂Nb₃O₁₀, NaCaTa₃O₁₀, CaLaNb₂TiO₁₀, La₂Ti₂NbO₁₀, Ba₅Ta₄O₁₅, W₂O₇, RuO₂₊ₓ (wherein 0≦x≦0.1), Cs₄W₁₁O₃₆, or a combination thereof.

The metal oxide nanosheet may have an average lateral size of greater than or equal to about 0.5 micrometers (μm) and less than or equal to about 100 μm, and may have a thickness of less than or equal to about 10 nanometers (nm).

The intercalant may include at least one alkylammonium salt having 1 to 16 carbons.

The substrate may include a polycarbonate, a polyimide, a polyolefin, a polyetherimide, a polyester, a polyurethane, a polystyrene, a polyacrylonitrile, a copolymer thereof, a derivative thereof, or a combination thereof.

The first conductive layer is a discontinuous layer including an open space disposed between the metal oxide nanosheets, and an area ratio of the open space to the total area of the first conductive layer may be less than or equal to about 50%.

The surface treatment on the first conductive layer may include:

treating the surface of the first conductive layer with a polar solvent having a polarity index of greater than or equal to about 3.9 and having substantially no influence on transmittance of the substrate.

The polar solvent may include water, a C1 to C15 alcohol, a C3 to C15 ketone compound, an amino acid, a polypeptide, a C2 to C15 carboxylic acid compound, N,N-dimethylformamide, N,N-dimethylacetamide, dimethyl sulfoxide, N-methylpyrrolidone, hexamethylphosphoramide, or a combination thereof.

The surface treatment of the first conductive layer with a polar organic solvent may include:

contacting the surface of the first conductive layer to the polar organic solvent, and

removing the polar organic solvent from the first conductive layer surface.

The contacting the first conductive layer surface to the polar organic solvent may include adding by drops, spraying, or evaporating the polar organic solvent onto the surface of the first conductive layer surface.

The first conductive layer in which at least a portion of the intercalant is removed may have a carbon content of less than about 30 parts by weight, based on 100 parts by weight of the metal.

The first conductive layer in which at least a portion of the intercalant is removed may have surface roughness of less than or equal to about 0.5 nanometers when measured by atomic force microscopy.

The method may further include:

forming a second conductive layer including a conductive metal nanowire on the substrate prior to providing the first conductive layer on the substrate.

The method may further include:

providing a second conductive layer including a nanowire of a conductive metal on the surface of the first conductive layer from which at least a portion of the intercalant is removed.

The method may further include:

providing an overcoating layer on the second conductive layer.

The method may further include:

providing an overcoating layer on the surface of the first conductive layer from which at least a portion of the intercalant is removed.

According to another embodiment, the conductor is obtained by the above-mentioned method.

In another embodiment, an electronic device including the conductor is provided.

The electronic device may be a flat panel display, a touch screen panel, a solar cell, an e-window, an electrochromic mirror, a heat mirror, a transparent transistor, or a flexible display.

According to another embodiment, in the conductor including the first conductive layer including a plurality of metal oxide nanosheets, the first conductive layer is a discontinuous layer including an open space disposed between the metal oxide nanosheets, wherein an area ratio of the open space to the total area of the first conductive layer may be less than or equal to about 30%, and

wherein the first conductive layer include carbon at less than about 30 parts by weight, based on 100 parts by weight of the metal and has sheet resistance of less than or equal to about 1,000 ohms per square, transmittance of greater than or equal to about 85.0%, and haze of less than or equal to about 1.0%.

In some embodiments, the conductors may be prepared to have a reduced level of sheet resistance together with a relatively low haze and good light transmittance. The methods of the embodiments may be applied to a roll-to-roll coating process, making it possible to produce a conductor having various structures (e.g., a hybrid structure) with high productivity.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic view showing a process of preparing nanosheets using an intercalant (intercalation);

FIG. 2 is a schematic view showing a structure of a conductor manufactured according to an embodiment;

FIG. 3 is a schematic view showing a structure of a conductor manufactured according to another embodiment;

FIG. 4 is a schematic view showing a structure of a conductor manufactured according to a still another embodiment;

FIG. 5 is a cross-sectional schematic view of an electronic device (touch screen panel) according to an embodiment;

FIG. 6 is a graph of haze (percent, %) versus sheet resistance (ohms per square, ohm/sq) showing a relationship between haze and sheet resistance in Example 1;

FIG. 7 is a graph of transmittance (percent, %) and haze (percent, %) versus number of solvent washings, showing a transmittance and haze change depending upon the number of solvent washes in Example 6;

FIG. 8 is a graph of transmittance (percent, %) and haze (percent, %) versus number of solvent washings, showing a transmittance and haze change depending upon the number of solvent washes in Example 7;

FIG. 9 is a graph showing atomic force microscopy analysis results of the conductive layer including RuO₂₊ₓ nanosheets before the ethanol treatment in Example 8; and

FIG. 10 is a graph showing atomic force microscopy analysis results of the conductive layer including RuO₂₊ₓ nanosheets after the ethanol treatment in Example 8.

### DETAILED DESCRIPTION

Exemplary embodiments will now be described more fully with reference to the accompanying drawings, in which some exemplary embodiments are shown. The exemplary embodiments may, however, be embodied in many different forms and should not be construed as being limited to the embodiments set forth herein; rather, these exemplary embodiments are provided so that this disclosure will be thorough and complete, and will fully convey the scope of the exemplary embodiments of inventive concepts to those of ordinary skill in the art. Therefore, in some exemplary embodiments, well-known process technologies may not be explained in detail in order to avoid unnecessarily obscuring of aspects of the exemplary embodiments. If not defined otherwise, all terms (including technical and scientific terms) in the specification may be defined as commonly understood by one skilled in the art. The terms defined in a generally-used dictionary are not to be interpreted ideally or exaggeratedly unless clearly defined otherwise. In addition, unless explicitly described to the contrary, the word “comprise” and variations such as “comprises” or “comprising” will be understood to imply the inclusion of stated elements but not the exclusion of any other elements.

Further, the singular includes the plural unless mentioned otherwise.

Exemplary embodiments are described herein with reference to illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

In the drawings, the thickness of layers, regions, etc., are exaggerated for clarity. Like reference numerals designate like elements throughout the specification.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise. Unless specified otherwise, the term “or” means “and/or.” As used herein, the term “and/or” includes any and all combinations of one or more of the associated items. Expressions such as “at least one of,” when preceding a list of elements, modify the entire list of elements and do not modify the individual elements of the list.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, the term “combination thereof” refers to a mixture, a stacked structure, a composite, an alloy, a blend, a reaction product, or the like.

As used herein, the term “alkyl group” may refer to a straight or branched chain saturated aliphatic hydrocarbon group having the specified number of carbon atoms and having a valence of at least one.

As used herein, the term “(meth)acrylate” refers to acrylate and methacrylate.

According to an embodiment, a method of preparing a conductor including a first conductive layer including a plurality of metal oxide nanosheets includes:

preparing a coating liquid including a plurality of metal oxide nanosheets, wherein an intercalant is attached to a surface of the metal oxide nanosheets;

applying the coating liquid to a substrate to provide a first conductive layer including a plurality of metal oxide nanosheets; and

treating the surface of the first conductive layer to remove at least a portion of the intercalant.

The coating the coating liquid on a substrate to provide a first conductive layer and the treating the surface of the first conductive layer may be repeated one or more times (e.g., at least 2 times, at least 3 times, or at least 4 times).

The metal oxide may be electrically conductive. For example, the metal oxide may have resistivity at a bulk material state of, for example, less than or equal to about 1×10¹² Ohms per centimeter (Ohm/cm) at room temperature (about 25° C.). The metal oxide nanosheet may include TiₓO₂ (wherein x=0.6 to 1.4, or 0.8 to 1.0, hereinafter referred to as titanium oxide), RuO₂₊ₓ (wherein −0.3≦x≦0.3, or 0≦x≦0.1, hereinafter referred to as ruthenium oxide), Ti₃O₇, Ti₄O₉, Ti₅O₁₁, Ti₁₋ₓCoₓO₂ (wherein 0<x≦0.2), Ti₁₋ₓ FeₓO₂ (wherein 0<x≦0.4), Ti₁₋ₓMnₓO₂ (wherein 0<x≦0.4), Ti_{0.8-x/4}Fe_{x/2}CO_{0.2-x/4}O₂ (wherein x=0.2, 0.4, or 0.6), MnO₂, Mn₃O₇, Mn₁₋ₓCoₓO₂ (wherein 0<x≦0.4), Mn₁₋ₓFeₓO₂ (wherein 0<x≦0.2), TiNbO₅, Ti₂NbO₇, TiTaO₅, Nb₃O₈, Nb₆O₁₇, TaO₃, LaNb₂O₇, La_{0.90}Eu_{0.05}Nb₂O₇, Eu_{0.56}Ta₂O₇, SrTa₂O₇, Bi₂SrTa₂O₉, Ca₂Nb₃O₁₀, Sr₂Nb₃O₁₀, NaCaTa₃O₁₀, CaLaNb₂TiO₁₀, La₂Ti₂NbO₁₀, Ba₅Ta₄O₁₅, W₂O₇, Cs₄W₁₁O₃₆, or a combination thereof. The metal oxide nanosheet may have an average lateral size of greater than or equal to 0.5 micrometers (μm), for example, greater than or equal to about 1 μm, greater than or equal to about 2 μm, greater than or equal to about 3 μm, greater than or equal to about 4 μm, greater than or equal to about 5 μm, or greater than or equal to about 6 μm. The metal oxide nanosheet may have an average lateral size of less than or equal to about 100 μm, for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 9 μm, less than or equal to about 8 μm, or less than or equal to about 7 μm. The metal oxide nanosheet may have an average thickness of less than or equal to about 10 nanometers (nm), for example, less than or equal to about 5 nm, less than or equal to about 3 nm, less than or equal to about 2.5 nm, or less than or equal to about 2 nm. The metal oxide nanosheet may have an average thickness of greater than or equal to about 1 nm, for example, greater than about 1 nm. When the nanosheet has a size of about 0.5 to about 100 μm, contact resistance between nanosheets is minimized, so as to reduce sheet resistance of a transparent electrode. When the nanosheet has an average thickness of less than or equal to about 3 nm, the transmittance is increased, so that the transmittance of transparent electrode is expected to be enhanced. The plurality of metal oxide nanosheets may be prepared by chemical exfoliation (e.g., intercalation) of a layered metal oxide.

For example, the nanosheets of titanium oxide or ruthenium oxide may be prepared from an alkaline metal titanium oxide (MTiO₂) or an alkaline metal ruthenium oxide (MRuO₂) (wherein M=Na, K, Rb, or Cs), which for example has a layered structure (for example, M-RuO₂-M-RuO₂-M in a case of an alkaline metal ruthenium oxide). The alkaline metal titanium oxide or the alkaline metal ruthenium oxide may be obtained by mixing an alkaline metal compound and titanium oxide or ruthenium oxide and baking or melting the obtained mixture at an appropriate temperature, for example, about 500° C. to about 1,000° C. When the obtained alkaline metal titanium oxide or alkaline metal ruthenium oxide is treated with an acid solution, at least a portion of the alkali metal is proton-exchanged to provide a proton-type alkaline metal titanate hydrate or a proton-type alkaline metal ruthenate hydrate. The obtained proton-type alkaline metal titanate hydrate or the obtained proton-type alkaline metal ruthenate hydrate are reacted with an alkylammonium or alkylamine to provide an alkylammonium- or alkylamine-substituted compound, and it is mixed with a solvent and exfoliated to nanosheets, so that titanium oxide nanosheets or ruthenium oxide nanosheets may be obtained. The solvent may be a high dielectric solvent. The solvent may be at least one selected from water, alcohol, acetonitrile, dimethyl sulfoxide, dimethyl formamide, and propylene carbonate.

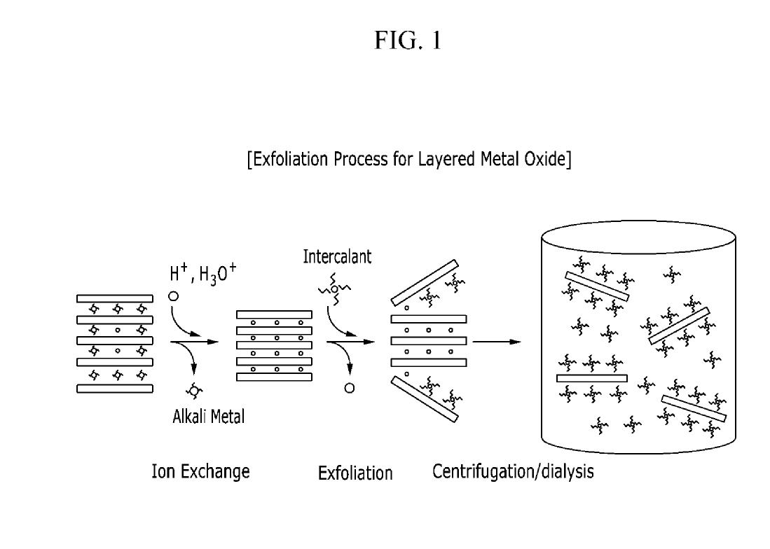

FIG. 1 is a schematic vies showing an exfoliation process into nanosheets by a layered metal oxide intercalation, in a non-limiting embodiment. Referring to FIG. 1, in the intercalation exfoliation, an alkali metal-added layered metal oxide is obtained, and the alkali metal in the layered structure of oxide is ion-exchanged with H⁺ or H₃O⁺ through the ion exchange. Subsequently, the ion-exchanged metal oxide having the layered structure is reacted with an organic molecule (i.e., an intercalant) having at least a size of about the interlayer distance of the layered structure to substitute H⁺ or H₃O⁺ with the intercalant. The intercalant molecule is intercalated between metal oxide layers to widen the gap between layers of the metal oxide, thus causing the interlayer separation, and with adding the intercalant-substituted metal oxide to a solvent and stirring the same, it may be exfoliated to provide metal oxide nanosheets. The resulting material including the obtained nanosheets is centrifuged and dialyzed, if desired, to remove the intercalant remaining after removing non-exfoliated particles. The intercalant may be at least one alkylammonium salt having 1 to 16 carbon atoms. Non-limiting examples of the alkylammonium salt may be a tetramethylammonium compound such as tetramethylammonium hydroxide, a tetraethylammonium compound such as tetraethylammonium hydroxide, a tetrapropylammonium compound such as tetrapropylammonium hydroxide, a tetrabutylammonium compound such as tetrabutylammonium hydroxide, a benzylmethylammonium compound such as benzylmethylammonium hydroxide, but are not limited thereto.

The metal oxide nanosheets obtained by the intercalation necessarily include the intercalant attached to the surface. This is because the metal oxide nanosheets have a negative charge, but the intercalant has a positive charge.

The coating liquid including a plurality of metal oxide nanosheets, wherein an intercalant is attached to a surface of the metal oxide nanosheets may be prepared according to a known method. For example, the coating liquid may be prepared by mixing a colloidal aqueous solution including a plurality of metal oxide nanosheets, wherein an intercalant is attached to a surface of the metal oxide nanosheets, in the predetermined concentration with a C1 to C15 alcohol, a binder, and selectively, a dispersing agent (e.g., a C2 to C20 organic acid).

The binder may play a role of appropriately adjusting viscosity of the coating liquid or enhancing adherence of nanosheets on the substrate. Non-limiting examples of the binder may be methyl cellulose, ethyl cellulose, hydroxypropyl methyl cellulose (HPMC), hydroxypropyl cellulose (HPC), xanthan gum, polyvinyl alcohol (PVA), polyvinylpyrrolidone (PVP), carboxymethyl cellulose, hydroxyethyl cellulose, or a combination thereof. The amount of binder may be appropriately selected, and is not particularly limited.

The content of each component in the coating liquid is not particularly limited, and may be appropriately adjusted. In an embodiment, it includes 30-70% of a nanosheet aqueous solution (nanosheet concentration: 0.001-10.00 grams per liter, g/L), a predetermined concentration (0.05 percent by weight (wt %)-5 wt %) of a binder aqueous solution, for example, 5-30% of a hydroxypropyl methylcellulose aqueous solution, 1-20% of a C1 to C10 alcohol, for example, ethanol and isopropanol, and 10-50% of water (total amount: 100%), but is not limited thereto. Although the concentration may be different depending upon the nature of metal oxide, in the case of RuO₂₊ₓ nanosheets, the nanosheet aqueous solution with a concentration of greater than or equal to about 0.001 g/L may produce a transparent electrode having an improved-level of electrical conductivity.

The prepared coating liquid is coated on a substrate to provide a first conductive layer including a plurality of metal oxide nanosheets.

The substrate is not particularly limited, but may be appropriately selected. The substrate may be a transparent substrate. The substrate may be a flexible substrate. A material of the substrate is not particularly limited, and it may be a glass substrate, a semiconductor substrate such as Si, a polymer substrate, or a combination thereof, or may be a substrate laminated with an insulation layer and/or a conductive layer. For non-limiting examples, the substrate may include inorganic materials such as an oxide glass or glass, polyesters such as polyethylene terephthalate, polybutylene terephthalate, or polyethylene naphthalate, polycarbonate, a polyolefin such as polybutylene, or polyethylene, polyetherimide, acryl-based polymers, polyurethane, polystyrene, polyacrylonitrile, cellulose, copolymers thereof, or derivatives thereof, various polymers such as polyimide, organic/inorganic hybrid materials, or combinations thereof. The thickness of the substrate is also not particularly limited, but may be appropriately selected according to the nature of the final product. For example, the substrate may have a thickness of greater than or equal to about 0.5 μm, for example, greater than or equal to about 1 μm, or greater than or equal to about 10 μm, but is not limited thereto. The thickness of the substrate may be less than or equal to about 1 millimeters (mm), for example, less than or equal to about 500 μm, or less than or equal to about 200 μm, but is not limited thereto. An additional layer (e.g., an undercoat) may be provided between the substrate and the conductive layer, if needed (e.g., for controlling a refractive index).

The coating method of a coating liquid is not particularly limited, but may be appropriately selected. For example, the coating may be performed by bar coating, blade coating, slot die coating, spray coating, spin coating, gravure coating, inkjet printing, or a combination of these methods. The nanosheets may contact each other for providing an electrical connection. When the prepared nanosheets are physically connected to provide a layer as thin as possible, it may provide further improved transmittance. The obtained first conductive layer may selectively undergo a drying and/or heating treatment, before or after the surface treatment.

The first conductive layer is a discontinuous layer including an open space between metal oxide nanosheets, and the area ratio of open space to the total area of the first conductive layer may be less than or equal to about 50%, for example, less than or equal to about 40%, or less than or equal to about 30%.

According to an embodiment, the method includes removing at least a portion of an intercalant attached to the surface of a plurality of nanosheets by treating the surface of the first conductive layer. By removing at least a portion of the intercalant, the contact resistance and the sheet resistance of the obtained conductor may be reduced, and the surface roughness and the haze may be decreased, as well. In addition, the removal of at least a portion of the intercalant may improve the adherence to the overcoating layer, which will be explained below, and enhance the transmittance of the final product of an electrode.

Without being bound by any particular theory, it is believed that the technical effects of the present method may be obtained for the following reasons.

The two-dimensional nanosheets of the layered inorganic solid obtained by the chemical exfoliation are considered to be building blocks for preparing a conductor having a novel structure, and the conductor including a layer of two-dimensional nanosheets may be expected to have improved conductivity and light transmittance. However, the conductors may have relatively high contact resistance (or relatively high sheet resistance) and high surface roughness at a desirable transmittance and may have high surface haze.

The metal oxide nanosheets obtained by the intercalation necessarily include the intercalant attached to their surface, wherein the intercalant is an essential factor in the manufacturing process since it may prevent the agglomeration of nanosheets and may maintain the dispersion in a follow-up application process using the nanosheets. However, the inventors found that the intercalant may inhibit the contact between nanosheets when applying the same to the conductor, and particularly, the conductive layer formed with nanosheets may cause an increase in the surface roughness of the conductive layer. In addition, when the overcoating layer is formed on the conductive layer to protect the conductive layer, the intercalant which is attached to the surface of the nanosheets may have a negative influence on the adherence between the conductive layer and the overcoating layer. In the method of manufacturing a conductor according to an embodiment, the surface of the first conductive layer is treated to remove at least a portion of the intercalant, after providing the first conductive layer including nanosheets of which the intercalant is attached to the surface.

The surface treatment of the first conductive layer includes treating the surface of the first conductive layer with a polar solvent having a polarity index of greater than or equal to about 3.9. The polar solvent may have no influence on transmittance of the substrate. Having no influence on transmittance of the substrate means that the transmittance of the substrate is not substantially changed after contacting the solvent with the substrate.

The polar solvent may include water, a C1 to C15 alcohol such as ethanol, ethanol, propanol, butanol, or pentanol, a C3 to C15 ketone compound, an amino acid, a polypeptide, a C2 to C15 carboxylic acid compound, N,N-dimethylformamide, N,N-dimethylacetamide, dimethyl sulfoxide, N-methylpyrrolidone, hexamethylphosphoramide, or a combination (for example, mixture) thereof. The polar solvent may include an organic solvent. The solvent may include an organic solvent having miscibility with water.

The treating the surface of the first conductive layer with a polar organic solvent may include contacting the surface of the first conductive layer with the polar solvent and then removing the polar solvent from the surface of the first conductive layer. For example, the contacting the surface of the first conductive layer with the polar organic solvent may include adding by drops, spraying, or evaporating the polar organic solvent to the surface of the first conductive layer. According to an embodiment, the contacting the surface of the first conductive layer with the polar organic solvent excludes immersing or dipping the same in the polar solvent.

The first conductive layer in which at least a portion of the intercalant is removed may include carbon in an amount of less than about 30 parts by weight, for example, less than or equal to about 29 parts by weight, less than or equal to about 28 parts by weight, less than or equal to about 27 parts by weight, or less than or equal to about 26 parts by weight, based on 100 parts by weight of the metal.

The first conductive layer in which at least a portion of the intercalant is removed may have surface roughness of less than or equal to about 0.5 nm, for example, less than or equal to about 0.4 nm, when measured by atomic force microscopy. The first conductive layer in which at least a portion of the intercalant is removed may have a decreased average thickness (e.g., decreased by greater than or equal to about 10%, greater than or equal to about 20%, or greater than or equal to about 30%) compared to the thickness measured before the removing.

The surface treatment of the first conductive layer may include applying energy (e.g., heat energy or activation energy rays such as UV) onto the surface of the first conductive layer.

The conductor manufacturing method according to an embodiment may further include providing a second conductive layer including a nanowire of a conductive metal on the substrate before forming a first conductive layer on the substrate. Alternatively, the conductor manufacturing method according to an embodiment may further include providing a second conductive layer including a nanowire of a conductive metal on the first conductive layer surface in which at least a part of the intercalant is removed.

The conductive metal may include silver (Ag), copper (Cu), gold (Au), aluminum (Al), cobalt (Co), palladium (Pd), or a combination thereof (e.g., an alloy thereof, or a nanometal wire having two or more segments). For example, the conductive metal nanowire may be a silver nanowire.

The conductive metal nanowire may have an average diameter of less than or equal to about 50 nm, for example, less than or equal to about 40 nm, or less than or equal to about 30 nm. The length of the conductive metal nanowire is not particularly limited, but may be appropriately selected according to the diameter. For example, the length of conductive metal nanowire may be greater than or equal to about 1 μm, greater than or equal to about 2 μm, greater than or equal to about 3 μm, greater than or equal to about 4 μm, or greater than or equal to about 5 μm, but is not limited thereto. According to another embodiment, the length of the conductive metal nanowire may be greater than or equal to about 10 μm, for example, greater than or equal to about 11 μm, greater than or equal to about 12 μm, greater than or equal to about 13 μm, greater than or equal to about 14 μm, or greater than or equal to about 15 μm. The conductive metal nanowire may be manufactured by a known method or may be commercially available in the market. The nanowire may include a polymer coating such as polyvinylpyrrolidone on the surface thereof.

The second conductive layer including a nanowire may be obtained by coating an appropriate coating composition on a substrate or a first conductive layer and removing a solvent. The coating composition may further include an appropriate solvent (e.g., water, an organic solvent miscible or immiscible with water, or the like), a binder, and a dispersing agent (e.g., hydroxypropyl methylcellulose or the like).

For example, the ink composition including the conductive metal nanowire may be commercially available or may be prepared according to any known method. For example, the ink composition may have the composition shown in Table 1, but is not limited thereto.

TABLE 1

| | Material | Amount |
|---|---|---|
| Conductive | Conductive metal (e.g. Ag) nanowire aqueous | 5-40% |
| metal | solution (concentration: 0.001-10.0 wt %) | |
| Solvent | Water | 20-70% |
| | Alcohol (ethanol) | 10-40% |
| Dispersing | Hydroxypropyl methylcellulose aqueous solution | 1-10% |
| agent | (0.05-5 wt %) | |

Other specific details of the solvent, the binder, the dispersing agent, and the coating method or the like are the same as described above.

The method according to an embodiment may further include forming an overcoating layer (OCL) on the second conductive layer. Alternatively, the method according to an embodiment may further include forming an overcoating layer on the first conductive layer surface in which at least a portion of the intercalant is removed. The thermosetting polymer and the ultraviolet (UV)-curable polymer for the overcoating layer (OCL) may be used as known. According to an embodiment, the thermosetting polymer and ultraviolet (UV) curable polymer for an overcoating layer (OCL) may include perfluoropolymer having a (meth)acrylate group, urethane (meth)acrylate, epoxy(meth)acrylate, poly(meth)acrylate having a (meth)acrylate group, or a combination thereof. The overcoating layer may further include an inorganic oxide particulate (e.g., silica particulate). The method of forming the OCL on the conductive thin film from the above-mentioned materials is also known, and is not particularly limited.

According to an embodiment, the manufacturing method may be applied to a roll-to-roll (R2R) process, making it possible to mass-produce a conductor including metal oxide nanosheets. In addition, the method may contribute to a decrease in the contact resistance between nanosheets of the obtained conductor, and thus may allow for the conductor to have a desired sheet resistance. In addition, the adhesion of the conductive layer with the overcoating layer may be enhanced, and thus may lead to the improved stability of the conductor.

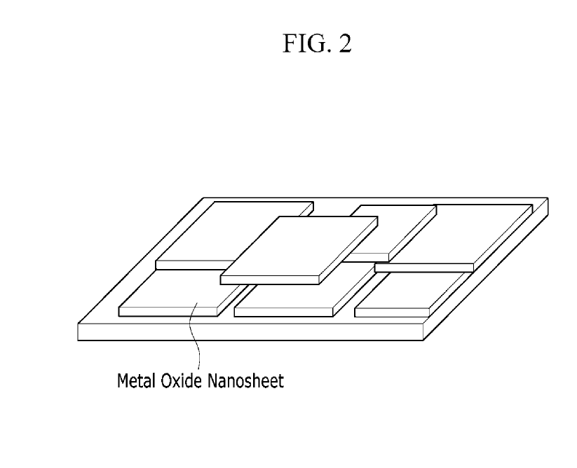

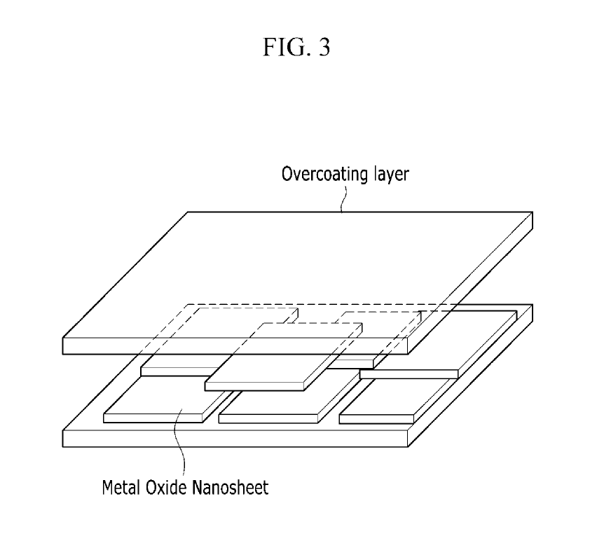

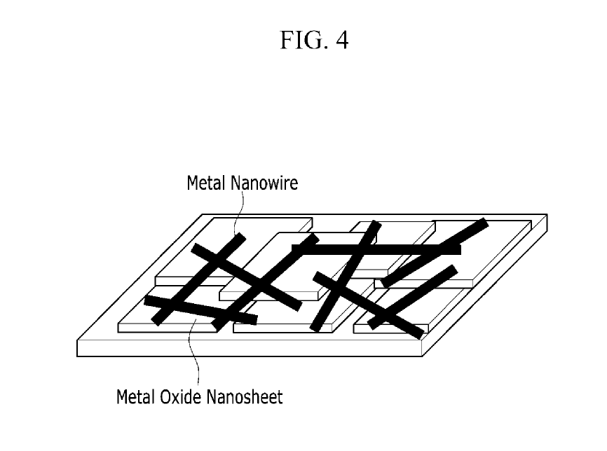

According to an embodiment, the conductor obtained by the manufacturing method may include a first conductive layer contacting a plurality of nanosheets to provide an electrical connection (reference: FIG. 2). An overcoating layer may be disposed on the first conductive layer or the second conductive layer (reference: FIG. 3). According to another embodiment, the conductor obtained by the manufacturing method may include a second conductive layer including conductive metal nanowires on one side of the first conductive layer (reference: FIG. 4). The conductor obtained by the manufacturing method may include a substrate on a surface opposite to the interface between the first conductive layer and the second conductive layer (e.g., one surface of the first conductive layer or the second conductive layer). The detailed descriptions of the first conductive layer, the second conductive layer, the substrate, and the overcoating layer are same as described above.

Various researches on developing a flexible transparent electrode material having high conductivity in the visible light region have been performed. In this regard, the metal may have a high electron density and high electrical conductivity. However, most metals easily react with oxygen in the presence of air to easily generate an oxide on the surface thereof, thus significantly decreasing the conductivity. It has been attempted to reduce the surface contact resistance by using a ceramic material having decreased surface oxidation with excellent conductivity. However, the conventional conductive ceramic material (e.g., ITO) are not always available; they are non-flexible, and do not possess the metal-level conductivity. On the other hand, after the conductive characteristics of the layered material of graphene were first reported, a monoatomic layer thin film of a layered structure material having a weak binding force has been an object of active research. Particularly, substantial efforts on applying graphene to a highly flexible transparent conductive layer material have been undertaken to substitute for indium tin oxide (ITO) having weak mechanical properties. However, it is difficult to provide a satisfactory level of transmittance with graphene since graphene has a high absorption coefficient (a), and it is hard to use the material at a thickness of four or more monoatomic layers. Meanwhile, most transition metal dichalcogenides (TMD), which are known to have a layered crystalline structure, may have satisfactory transmittance, but it is not easy to apply them to a transparent conductive layer since conductivity thereof is almost at a semiconductor level.

On the other hand, a first conductive layer including metal oxide nanosheets formed by the method (exfoliated by intercalation) may have improved conductivity and improved light transmittance, and may contribute to flexibility of a conductor including the same, so it may be applied to a conductor requiring flexibility, for example, a flexible transparent conductive layer or the like.

The conductor having this structure may provide improved flexibility as well as enhanced conductivity and enhanced light transmittance. The conductor may have light transmittance of greater than or equal to about 85%, for example, greater than or equal to about 88%, or greater than or equal to about 89%, for visible light (e.g., light having a wavelength of about 390 nm to about 700 nm) at a thickness of less than or equal to about 100 nm. When the conductor is measured with a specimen having a size of greater than or equal to about 10 centimeters (cm)×10 cm according to the Van der Pauw method, the sheet resistance is less than or equal to about 1,000 ohm/sq, for example, less than or equal to about 500 ohm/sq, less than or equal to about 90 ohm/sq, less than or equal to about 80 ohm/sq, less than or equal to about 70 ohm/sq, less than or equal to about 60 ohm/sq, less than or equal to about 50 ohm/sq, less than or equal to about 40 ohm/sq, less than or equal to about 39 ohm/sq, less than or equal to about 38 ohm/sq, less than or equal to about 37 ohm/sq, less than or equal to about 36 ohm/sq, or less than or equal to about 35 ohm/sq. When the haze of the conductor is measured using a haze meter (e.g., NDH-7000 SP manufactured by NIPPON DENSHOKU INDUSTRIES CO., LTD. and the like) according to ASTM D 1003, ISO 13468, or ISO 14782, it may be less than or equal to about 10.0%, for example, less than or equal to about 5.0%, or less than or equal to about 2.0%.

In another embodiment, an electronic device includes the conductor.

The electronic device may be a flat panel display, a touch screen panel, a solar cell, an e-window, an electrochromic mirror, a heat mirror, a transparent transistor, or a flexible display.

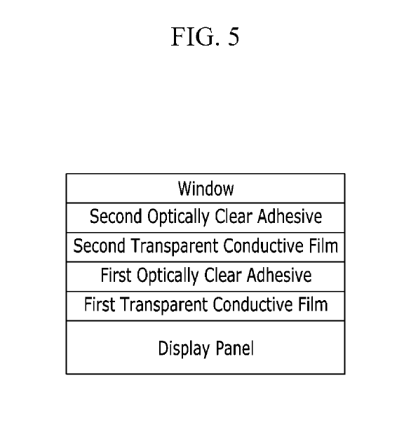

In an exemplary embodiment, the electronic device may be a touch screen panel (TSP). The detailed structure of the touch screen panel is well known. The schematic structure of the touch screen panel is shown in FIG. 5. Referring to FIG. 5, the touch screen panel may include a first transparent conductive film, a first transparent adhesive film (e.g., an optically clear adhesive (OCA)) film, a second transparent conductive film, a second transparent adhesive film, and a window for a display device, disposed in that order on a panel for a display device (e.g., an LCD panel). The first transparent conductive layer and/or the second transparent conductive layer may be the conductor or a hybrid structure.

In addition, an example of applying the conductor to a touch screen panel (e.g., a transparent electrode of TSP) is illustrated, but the conductor may be used as an electrode for other electronic devices including a transparent electrode without a particular limit. For example, the conductor may be applied as a pixel electrode and/or a common electrode for a liquid crystal display (LCD), an anode and/or a cathode for an organic light emitting diode device, or a display electrode for a plasma display device.

Hereinafter, the embodiments are illustrated in more detail with reference to examples. These examples, however, are not in any sense to be interpreted as limiting the scope of this disclosure.

### EXAMPLES

Measurement:

[1] Measurement of sheet resistance: the sheet resistance is measured as follows.

Measurer: Mitsubishi Loresta-GP (MCP-T610), ESP-type probes (MCP-TP08P)

Sample size: width 20 centimeters (cm)×length 30 cm

Measurement: average after repeating the measurement at least 9 times

[2] Light transmittance measurement: light transmittance is measured as follows.

Measurer: NIPPON DENSHOKU INDUSTRIES (NDH-7000 SP)

Sample size: width 20 cm×length 30 cm

Sample Measurement: average after repeating the measurement at least 9 times

[3] Haze Measurement: haze is measured as follows.

Measurer: NIPPON DENSHOKU INDUSTRIES (NDH-7000 SP)

Sample size: width 20 cm×length 30 cm

Sample Measurement: average after repeating the measurement at least 9 times

[4] Abrasion resistance test: the test is performed using a wiper manufactured from Yuhan Kimberly, Ltd. (product name: Kimtech Science medium-size)

The measurement is conducted by scrubbing the specimen with a wiper and then monitoring film damages by the naked eye

[5] Scanning Electron Microscope (SEM) and Atomic Force Microscope (AFM) analysis: a thickness of a nanosheet, a thickness of a conductive layer, and surface roughness of the conductive layer are measured by performing a scanning electron microscope and atomic force microscope analysis using the following devices.

Electron microscope: FE-SEM (Field Emission Scanning Electron Microscopy) Hitachi (SU-8030)

Scanning Prove Microscope (SPM): Bruker (Icon)

### Preparation Example 1

### Preparation of Ruthenium Oxide Nanosheets

K₂CO₃ and RuO₂ are mixed in a 5:8 mole ratio, and the mixture is shaped into pellets. 4 g of the obtained pellets is introduced into an alumina crucible and heat-treated in a tube furnace at 850° C. for 12 h under a nitrogen atmosphere. The total weight of the pellets may be adjusted within a range of 1 gram (g) to 20 g. Subsequently, the furnace is cooled to room temperature, and the treated pellets are taken out and ground to provide a fine powder.

The obtained fine powder is washed with about 100 milliliters (mL) to 4 liters (L) of water for 24 hours (h) and filtered to provide a powder. The obtained powder has a composition of K_{0.2}RuO_{2.1}.nH₂O. The K_{0.2}RuO_{2.1}.nH₂O powder is added to a 1 M of HCl solution and agitated for 3 days (d) and filtered to provide only a powder. The obtained powder has a composition of H_{0.2}RuO_{2.1}.

1 g of the obtained H_{0.2}RuO_{2.1} powder is added to 250 mL of an aqueous solution including TMAOH and TBAOH and agitated for greater than or equal to 10 d. In the aqueous solution, the concentrations of TMAOH and TBAOH are TMA+/H+=3, TBA+/H+=3, respectively. After completing all processes, the final solution is centrifuged under the conditions of 2,000 revolutions per minute (rpm), 30 min, and a floating intercalant is removed using a dialysis tube to provide an aqueous colloid solution including the exfoliated RuO₂₊ₓ nanosheets.

From the FE-SEM analysis results, it follows that the nanosheets have an average length of 1.5 micrometers (μm). The obtained nanosheets undergo XRD analysis. From the results, it follows that the interlayer distance is 0.935 nanometers (nm).

### Example 1

A coating liquid including RuO₂₊ₓ nanosheets obtained from Preparation Example 1 and having the following composition is prepared.

Aqueous dispersion liquid of the obtained RuO₂₊ₓ nanosheets: 0.9 g

HPMC aqueous solution (0.3%): 0.5 g

Alcohol: 2.5 g

Water: 2.7 g

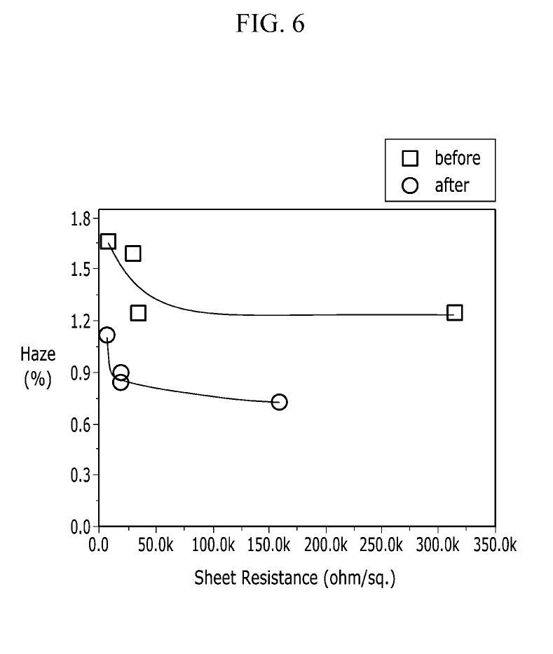

The obtained RuO₂₊ₓ nanosheet coating liquid is bar-coated on a polycarbonate substrate and dried at 85° C. under air to provide a first conductive layer. 50 mL of a polar solvent (ethanol, concentration 97%) is sprayed and treated on the surface of the obtained first conductive layer. Such process (preparation of the first conductive layer and surface treatment) is repeated several times to provide a conductor. The sheet resistance (ohm/sq), light transmittance (T %), and haze (%) of each of the obtained conductors are measured, and the results are shown in Table 2 and FIG. 6.

### Comparative Example 1

A conductor is obtained in accordance with the same procedure as in Example 1, except that the first conductive layer does not undergo surface treatment. For the obtained conductor, sheet resistance (ohm/sq), light transmittance (T %), and haze (%) are measured, and the results are shown in Table 2 and FIG. 6.

TABLE 2

| | |
|---|---|
| Comparative Example 1 | Example 1 |
| (before surface treatment) | (after surface treatment) |

| Rₛ (Ω/sq) | T %_{film} | Hz | Rₛ (Ω/sq) | T %_{film} | Hz |
|---|---|---|---|---|---|
| 314,600 | 86.3 | 1.24 | 159,000 | 86.0 | 0.69 |
| 23,500 | 84.5 | 1.24 | 18,940 | 84.2 | 0.83 |

From the results shown in Table 2, it follows that the conductor according to Example 1 may have significantly lower sheet resistance at the substantially equivalent level of light transmittance compared to the conductor according to Comparative Example 1, and may also have lower haze.

From the results shown in FIG. 6, it follows that the surface treated conductor according to Example 1 has lower haze at the equivalent level of sheet resistance compared to Comparative Example 1, although the haze is increased as the sheet resistance is decreased.

### Examples 2-1 and 2-2

[1] Preparing the coating liquid including RuO₂₊ₓ nanosheets and having the same composition as in Example 1. The obtained RuO₂₊ₓ nanosheet coating liquid is bar-coated on a polycarbonate substrate and dried at 85° C. in the presence of air to provide a first conductive layer. The obtained first conductive layer surface is sprayed with 50 mL of polar solvent (ethanol, concentration 97%). Such processes (preparation of the first conductive layer and surface treatment) are repeated once (Example 2-1) and twice (Example 2-2) to provide a conductor. The light transmittance (T %) and a haze (%) of each of the obtained conductors are measured, and the results are shown in Table 3.

[2] Providing an overcoating layer on the conductor obtained from [1] according to the following method.

The conductor obtained from [1] is fixed on a flat bottom and coated with a mixture of urethane acrylate and silica particles using a wired bar and then dried at room temperature for greater than or equal to 1 minute (min). Subsequently, the obtained resulting material is dried in an oven at 100° C. and cured by a UV curing machine to provide an overcoating layer.

The light transmittance (T %) and a haze (%) of each of the obtained conductors are measured, and the results are shown in Table 3.

### Comparative Example 2

The conductor is obtained in accordance with the same procedure as in Example 2-2, except that the first conductive layer does not undergo a surface treatment. The light transmittance (T %) and a haze (%) of each of the obtained conductors are measured, and the results are shown in Table 3.

TABLE 3

| | Surface of RuO₂₊ₓ first | | | | | |
|---|---|---|---|---|---|---|
| | conductive layer | | | After forming | | Abrasion test |
| | | | surface | overcoating layer | | result |
| | T %_{film} | Hz | treatment | T %_{film} | Hz | (OC adherence) |
| Example 2-1 | 89.0 | 0.47 | Yes | 91.2 (+2.2%) | 0.40-0.07 | Pass |
| Example 2-2 | 86.4 | 0.55 | Yes | 89.8 (+3.4%) | 0.32-0.23 | Pass |
| Comparative | 87.6 | 1.2 | NO | 89.9 (+2.3%) | 1.05-0.15 | Fail |
| Example 2 | | | | | | |

From Table 3, it follows that the conductive layers according to Examples 2-1 and 2-2 have significantly higher light transmittance, significantly lower haze, and significantly enforced adherence of the overcoating layer compared to the conductor according to Comparative Example 2.

### Example 3

[1] Preparing RuO₂₊ₓ nanosheet-containing coating liquid having the same composition as in Example 1. The obtained RuO₂₊ₓ nanosheet coating liquid is bar-coated on a polycarbonate substrate and dried at 85° C. under air to provide a first conductive layer. The obtained first conductive layer is sprayed with 50 mL of a polar solvent (ethanol, concentration of 97%). The processes (preparation of the first conductive layer and surface treatment) are repeated a predetermined number of times to provide a conductor. The light transmittance (T %) and haze (%) of the obtained conductor are measured, and the results are shown in Table 4.

[2] Providing the silver nanowire-containing coating liquid having the following composition.

3 g of a silver nanowire aqueous solution (concentration: 0.5 percent by weight (wt %), average diameter of silver nanowire: 30 nm)

solvent: 7 g of water and 3 g of ethanol

binder: 0.5 g of hydroxypropyl methyl cellulose aqueous solution (concentration: 0.3%)

The silver nanowire-containing composition is bar-coated on the first conductive layer obtained from [1] and dried at 85° C. for 1 min under air to provide a second conductive layer including silver nanowire. The sheet resistance (Rₛ), light transmittance (T %) and haze (%) of the obtained conductor are measured, and the results are shown in Table 4.

[3] Providing overcoating layer on the second conductive layer in accordance with the same procedure as in Example 2-1. The sheet resistance (Rₛ), light transmittance (T %) and haze (%) of the obtained conductor are measured, and the results are shown in Table 4.

### Comparative Example 3

The conductor is obtained in accordance with the same procedure as in Example 2, except that the surface treatment is not performed on the first conductive layer. The sheet resistance (Rₛ), light transmittance (T %) and haze (%) of the obtained conductor are measured, and the results are shown in Table 4.

TABLE 4

| | RuO₂ coating (bottom) | | | | | | | | | |
|---|---|---|---|---|---|---|---|---|---|---|
| | | | Surface | AgNW coating | | | OC coating | | | Abrasion |
| | T % | Hz | treatment | Rs | T % | Hz | Rs | T % | Hz | (OC adherence) |
| Example 3 | 88.7 | 0.2 | Yes | 35 | 86.6 | 1.18 | 36 | 89.2 | 0.99 | Pass |
| Comparative | 87.4 | 1.71 | NO | 1160 | 85.1 | 1.75 | NA | 87.6 | 1.24 | Fail |
| Example 3 | | | | | | | | | | |

From the results shown in Table 4, it follows that the conductors obtained from the examples have significantly lower sheet resistance, higher transmittance, and lower haze than the conductors obtained from the comparative examples. In addition, it is confirmed that the conductors obtained from the examples have significantly improved OCL adherence compared to those obtained from the comparative examples. In the case of Comparative Example 3, the provided overcoating layer is too irregular to measure the conductivity.

### Example 4

A conductor is prepared in accordance with the same procedure as in Example 3, except that the second conductive layer including silver nanowire is first formed on a substrate, and then the first conductive layer is formed on the obtained second conductive layer. The sheet resistance (Rₛ), light transmittance (T %) and haze (%) of the obtained conductor are measured, and the results are shown in Table 5.

### Comparative Example 4

A conductor is prepared in accordance with the same procedure as in Comparative Example 3, except that the second conductive layer including silver nanowire is first formed on a substrate, and then the first conductive layer is formed on the obtained second conductive layer. The sheet resistance (Rₛ), light transmittance (T %), and haze (%) of the obtained conductor are measured, and the results are shown in Table 5.

TABLE 5

| | | | | RuO₂ coating (top) | | | | | | | Abrasion |
|---|---|---|---|---|---|---|---|---|---|---|---|
| | AgNW coating | | | | | | Surface | OC coating | | | (OC |
| | Rₛ | T % | Hz | Rs | T % | Hz | treatment | Rₛ | T % | Hz | adherence) |
| Example 4 | 35 | 88.8 | 1.01 | 38 | 86.3 | 1.31 | Yes | 38 | 89.5 | 0.96 | Pass |
| Comparative | 35 | 86.8 | 1.01 | 38 | 86.3 | 1.30 | No | NA | 89.6 | 0.98 | Fail |
| Example 4 | | | | | | | | | | | |

From the results shown in Table 5, it follows that the conductors obtained from the examples have significantly lower sheet resistance, higher transmittance, and lower haze than the conductors according to the comparative examples. In addition, it is determined that the conductors according to the examples also have significantly improved OCL adherence compared to those according to the comparative examples.

### Example 5

A RuO₂₊ₓ nanosheet-contained coating liquid having the same composition as in Example 1 is prepared. The obtained RuO₂₊ₓ nanosheet coating liquid is bar-coated on a polycarbonate substrate and dried at 85° C. under air to provide a first conductive layer.

The obtained first conductive layer undergoes a surface treatment using ethanol (concentration: 97%), a surface treatment using isopropanol (concentration: 99%), a surface treatment using water, UV irradiation, and heating treatment as follows.

The surface treatment using ethanol or IPA: 50 mL of solvent is sprayed on the surface of a first conductive layer, and then the resulting material is dried in an oven at 85° C. for 3 min. The processes are repeated two times.

Surface treatment using water: 50 mL of water is sprayed on the surface of a first conductive layer surface, the resulting material is dried in an oven at 110° C. for 3 min, and the processes are repeated two times.

UV irradiation: light having a wavelength of 320-420 nm (intensity: 800 milliJoules, mJ) is irradiated on the first conductive layer for 2 min.

Heating treatment: a substrate formed with a first conductive layer is introduced into a vacuum oven at a temperature of 150° C. and maintained for 24 hours (h) (vacuum degree 1.1×10⁻² torr).

The sheet resistance, light transmittance, and haze of the obtained conductor are measured, and the results are shown in Table 6.

TABLE 6

| Surface treatment type | Rs(Ω/sq) | Transmittance (%) | Hz (%) |
|---|---|---|---|
| No surface treatment | 29,429 | 94.0 | 1.59 |
| Treatment with EtOH | 19,380 | 93.9 | 0.88 |
| Treatment with IPA | 22,557 | 93.7 | 0.92 |
| Treatment with water | 118,571 | 95.5 | 0.97 |
| UV irradiation | 29,325 | 93.8 | 1.55 |
| (800 mJ, 2 m/min) | | | |
| Heat treatment | 29,345 | 93.8 | 1.60 |
| (150° C., 24 h) | | | |

From the results of Table 6, it follows that the light transmittance of the conductor obtained by treating ethanol and IPA is not substantial changed, but the sheet resistance is decreased by 34% and 24%, respectively, and the haze is also decreased by 45% and 42%, respectively, compared to the conductor in which no surface treatment is performed. The conductor including nanosheets with simultaneously decreased sheet resistance and haze has drawn significant attention, given the general tendency that haze is increased when the sheet resistance is decreased.

From the results shown in Table 6, it follows that the light transmittance is increased and the haze is reduced, but the sheet resistance is suddenly increased by treating the surface of the conductor using water. This suggests that the nanosheets are significantly damaged by the treatment using water.

In the case of UV irradiation and vacuum heat treatment, sheet resistance and haze are insignificantly changed.

### Example 6

Preparing a coating liquid including RuO₂₊ₓ nanosheets obtained from Preparation Example 1 and having the following composition:

Aqueous dispersion liquid of the obtained RuO₂₊ₓ nanosheets: 0.9 g

HPMC aqueous solution (0.3%): 0.5 g

Isopropanol: 2.5 g

Water: 2.7 g

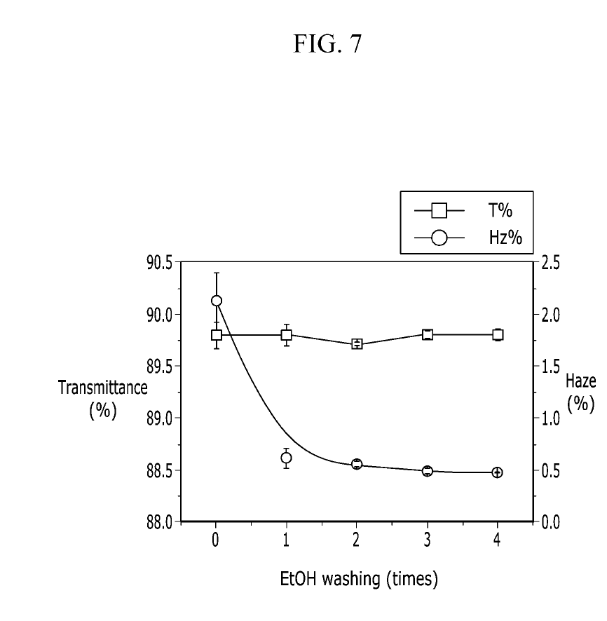

The obtained RuO₂₊ₓ nanosheet coating liquid is bar-coated on a polycarbonate substrate and dried at 85° C. in the presence of air to provide a first conductive layer. The obtained first conductive layer is sprayed with 50 mL of a polar solvent (ethanol, concentration 97%) and treated once to four times. After each surface treatment, the light transmittance (T %) and haze (%) of the obtained conductors are measured, and the results are shown in FIG. 7.

From the results shown in FIG. 7, it follows that the light transmittance is insignificantly changed by the surface treatment, haze is remarkably reduced by one surface treatment, and the haze difference between the four-time treated conductor and the one-time treated conductor is also insignificant.

### Example 7

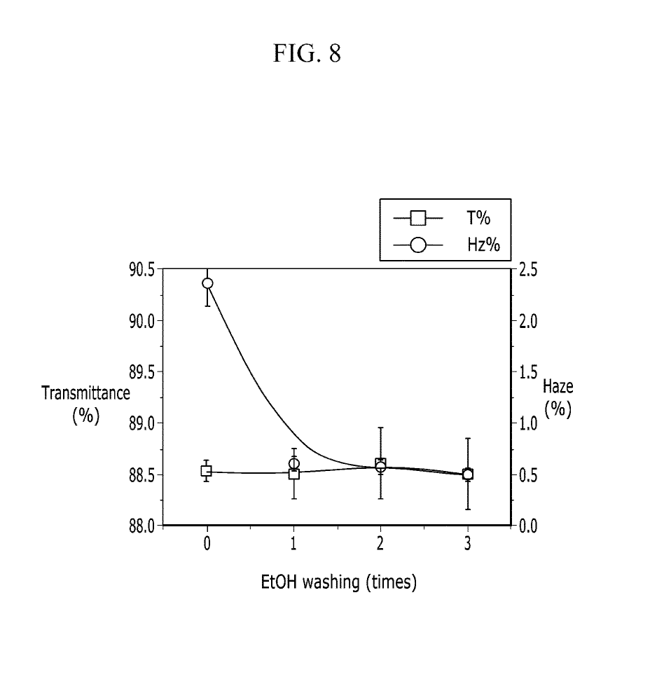

A conductor is obtained in accordance with the same procedure as in Example 6, except for the concentration of nanosheets (NS) in the coating liquid, and the results are shown in FIG. 8. From the results shown in FIG. 8, it follows that the light transmittance is little changed by the surface treatment, haze is remarkably reduced by a one-time surface treatment, and the haze difference between the four-time treated conductor and the one-time treated conductor is insignificant.

### Example 8

### Atomic Force Microscope Analysis and SEM/EDX Analysis

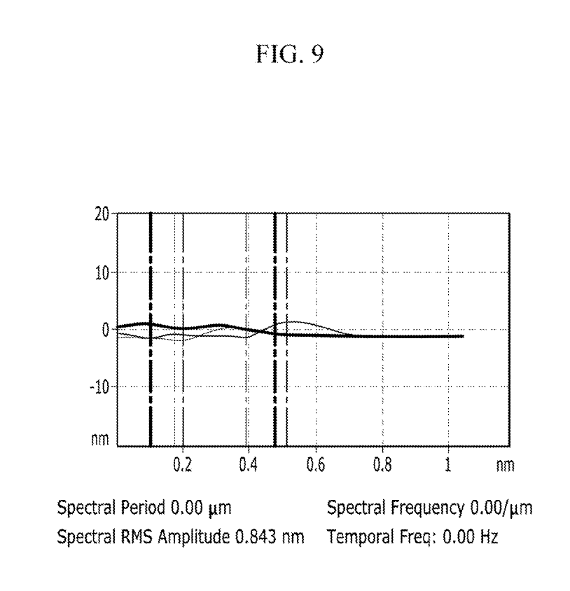

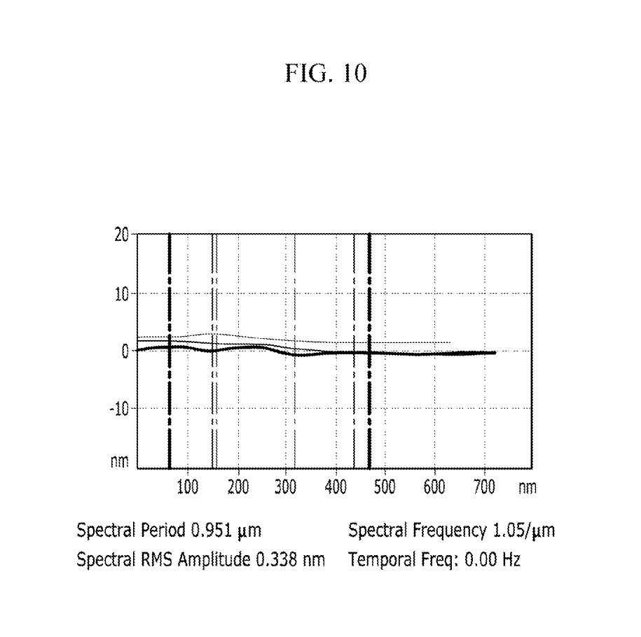

Before and after the surface treatment using ethanol in Example 1, an atomic force microscope analysis and a SEM/EDX analysis are carried out. The atomic force microscopic analysis results are shown in FIG. 9 (before the treatment) and FIG. 10 (after the treatment).

From the atomic microscopic analysis results, it follows that the average thickness is decreased by the surface treatment using ethanol from 1.9 nm (before the treatment) to 1.3 nm (after the treatment), and the surface roughness (Rₐ) is decreased from 0.69 nm (before treatment) to 0.34 nm (after treatment).

From the SEM/EDX analysis results, it is confirmed that the carbon content is decreased from 34 parts by weight, based on 100 parts by weight of metal before the treatment to 25 parts by weight after the treatment.

While this disclosure has been described in connection with what is presently considered to be practical exemplary embodiments, it is to be understood that the present disclosure is not limited to the disclosed embodiments, but, on the contrary, is intended to cover various modifications and equivalent arrangements included within the spirit and scope of the appended claims.

What is claimed is:

1. A method of preparing a conductor comprising a first conductive layer comprising a plurality of metal oxide nanosheets, the method comprising:
preparing a coating liquid comprising a plurality of metal oxide nanosheets, wherein an intercalant is attached to a surface of the nanosheets;
applying the coating liquid to a substrate to provide a first conductive layer comprising a plurality of metal oxide nanosheets; and
performing a surface treatment on the first conductive layer to remove at least a portion of the intercalant.

2. The method of claim 1, wherein the metal oxide nanosheet comprises TiₓO₂ (wherein x=0.6 to 1.4), RuO₂₊ₓ (wherein −0.3≦x≦0.3), TiₓO₂ (wherein x=0.8 to 1.0), Ti₃O₇, Ti₄O₉, Ti₅O₁₁, Ti₁₋ₓCoₓO₂ (wherein 0<x≦0.2), Ti₁₋ₓFeₓO₂ (wherein 0<x≦0.4), Ti₁₋ₓMnₓO₂ (wherein 0<x≦0.4), Ti_{0.8-x/4} Fe_{x/2}Co_{0.2-x/4}O₂ (wherein x=0.2, 0.4, or 0.6), MnO₂, Mn₃O₇, Mn₁₋ₓCoₓO₂ (wherein 0<x≦0.4), Mn₁₋ₓFeₓO₂ (wherein 0<x≦0.2), TiNbO₅, Ti₂NbO₇, TiTaO₅, Nb₃O₈, Nb₆O₁₇, TaO₃, LaNb₂O₇, La_{0.90}Eu_{0.05}Nb₂O₇, Eu_{0.56}Ta₂O₇, SrTa₂O₇, Bi₂SrTa₂O₉, Ca₂Nb₃O₁₀, Sr₂Nb₃O₁₀, NaCaTa₃O₁₀, CaLaNb₂TiO₁₀, La₂Ti₂NbO₁₀, Ba₅Ta₄O₁₅, W₂O₇, Cs₄W₁₁O₃₆, or a combination thereof.

3. The method of claim 1, wherein the metal oxide nanosheet has an average lateral size of greater than or equal to about 0.5 micrometers and less than or equal to about 100 micrometers and a thickness of less than or equal to about 10 nanometers.

4. The method of claim 1, wherein the intercalant comprises at least one C1 to C16 alkylammonium salt.

5. The method of claim 1, wherein the substrate comprises a polycarbonate, a polyolefin, a polyetherimide, a polyester, a polystyrene, a polyacrylonitrile, a polyurethane, an acryl polymer, a polyimide, a copolymer thereof, a derivative thereof, or a combination thereof.

6. The method of claim 1, wherein the first conductive layer is a discontinuous layer comprising an open space disposed between two adjacent metal oxide nanosheets, and an area ratio of the open space to the total area of the first conductive layer is less than or equal to about 50%.

7. The method of claim 1, wherein the surface treatment on the first conductive layer comprises:
treating the surface of the first conductive layer with a polar solvent having a polarity index of greater than or equal to about 3.9 and having no influence on transmittance of the substrate.

8. The method of claim 7, wherein the polar solvent comprises water, a C1 to C15 alcohol, a C3 to C15 ketone compound, an amino acid, a polypeptide, a C2 to C15 carboxylic acid compound, N,N-dimethylformamide, N,N-dimethylacetamide, dimethyl sulfoxide, N-methylpyrrolidone, hexamethylphosphoramide, or a combination thereof.

9. The method of claim 7, wherein the surface treatment of the first conductive layer with a polar organic solvent comprises:
contacting the first conductive layer surface with the polar organic solvent, and
removing the polar organic solvent from the first conductive layer surface.

10. The method of claim 7, wherein the contacting the first conductive layer surface to the polar organic solvent comprises:
adding by drops, spraying, or evaporating the polar organic solvent on the surface of the first conductive layer.

11. The method of claim 1, wherein the first conductive layer from which at least a portion of the intercalant is removed has a carbon content of less than about 30 parts by weight, based on 100 parts by weight of the metal.

12. The method of claim 1, wherein the first conductive layer from which at least a portion of the intercalant is removed has surface roughness of less than or equal to about 0.5 nanometers, measured by atomic force microscopy.

13. The method of claim 1, further comprising:
providing a second conductive layer comprising a conductive metal nanowire on the substrate prior to providing the first conductive layer on the substrate.

14. The method of claim 1, further comprising:
providing a second conductive layer comprising a nanowire of a conductive metal on the surface of the first conductive layer from which at least a portion of the intercalant is removed.

15. The method of claim 14, further comprising:
providing an overcoating layer on the second conductive layer.

16. The method of claim 1, further comprising:
providing an overcoating layer on the surface of first conductive layer in which at least a portion of the intercalant is removed.

17. A conductor prepared according to the method according to claim 1.

18. An electronic device comprising the conductor of claim 17.

19. The electronic device of claim 18, wherein the electronic device is a flat panel display, a touch screen panel, a solar cell, an e-window, an electrochromic mirror, a heat mirror, a transparent transistor, or a flexible display.

20. A conductor comprising a first conductive layer comprising a plurality of metal oxide nanosheets,
wherein the first conductive layer is a discontinuous layer comprising an open space disposed between metal oxide nanosheets, wherein an area ratio of the open space to the total area of the first conductive layer is less than or equal to about 30%, and
wherein the first conductive layer has a carbon content of less than about 30 parts by weight, based on 100 parts by weight of a metal, sheet resistance of less than or equal to about 1,000 ohms per square, transmittance of greater than or equal to about 85%, and haze of less than or equal to about 1.0%.
